(19) United States
(12) Patent Application Publication
(10) Pub. No.: US 2023/0009477 A1
(43) Pub. Date: Jan. 12, 2023

(54) MACHINE AND WAFER PROCESSING APPARATUS

(71) Applicant: CHANGXIN MEMORY TECHNOLOGIES, INC., Hefei city (CN)

(72) Inventor: HUNG-HSIANG LIN, Hefei City (CN)

(21) Appl. No.: 17/451,333

(22) Filed: Oct. 19, 2021

Related U.S. Application Data
(63) Continuation of application No. PCT/CN2021/107909, filed on Jul. 22, 2021.

(30) Foreign Application Priority Data
Jul. 7, 2021 (CN) 202110766666.8

(51) Int. Cl. H01L 21/683; B25B 11/00; H01J 37/32

(52) U.S. Cl. CPC H01L 21/6838; B25B 11/005; H01J 37/32715; H01J 37/32834; H01J 37/3244; H01J 2237/2007; H01J 2237/18

(57) ABSTRACT

A machine and a wafer processing apparatus are provided; the machine includes a body and an adjustment part. The body is configured to bear a wafer; the adjustment part is disposed in the body, and the adjustment part uses a vacuum suction to adjust a levelness of an in-process wafer.

### CROSS REFERENCE TO RELATED APPLICATION

This application is a continuation application of International Patent Application No. PCT/CN2021/107909, filed on Jul. 22, 2021, which claims priority to Chinese Patent Application No. 202110766666.8, filed with the Chinese Patent Office on Jul. 7, 2021 and entitled “MACHINE AND WAFER PROCESSING APPARATUS”. International Patent Application No. PCT/CN2021/107909 and Chinese Patent Application No. 202110766666.8 are incorporated herein by reference in their entireties.

### TECHNICAL FIELD

The present disclosure relates to the field of semiconductor technologies.

### BACKGROUND

A machine is an assistance apparatus in a wafer manufacture process, which is configured to bear a manufactured wafer. During the manufacture process, since plasma generated from a sprayer have different intensities, and due to a position where a gas extractor is disposed, the gas extractor has an extraction efficiency inside a wafer surface different from outside the wafer surface, thereby affecting an efficiency of generating a wafer film, and causing the manufactured wafer to have a high or low point in an interval, which causes the wafer to have a defect of poor uniformity and flatness, and affects a product yield.

Therefore, how to solve the above issue becomes a problem urgent to be solved by a person skilled in the art.

### SUMMARY

According to some embodiments, a first aspect of the present disclosure provides a machine including a body and an adjustment part. The body is configured to bear a wafer;

the adjustment part is disposed in the body, and the adjustment part uses a vacuum suction to adjust a levelness of an in-process wafer.

According to some embodiments, a second aspect of the present disclosure provides a wafer processing apparatus, including:

a housing with a reaction chamber;

at least one machine described above, the machine disposed in the reaction chamber;

a gas extractor disposed in the reaction chamber, the gas extractor is configured to adjust an efficiency of producing a wafer on the machine during a manufacture process; and

a gas feeder disposed in the reaction chamber, the gas feeder arranged opposite to the machine.

### BRIEF DESCRIPTION OF THE DRAWINGS

FIG. 1 is a partial schematic structural diagram of a machine according to an exemplary embodiment;

FIG. 2 is a partial schematic structural diagram of a machine according to an exemplary embodiment;

FIG. 3 is a top view of a carrying surface according to an exemplary embodiment; and

FIG. 4 is a schematic structural diagram of a wafer processing apparatus according to an exemplary embodiment.

### DETAILED DESCRIPTION

In order to facilitate to understand the present disclosure, a more complete description of the present disclosure is provided below with reference to the relevant drawings. Embodiments of the present disclosure are given in the drawings. However, the present disclosure may be implemented in a number of different ways without limiting to the embodiments described herein. Instead, the purposes of providing these embodiments are leading to a more thorough and complete understanding of the disclosure of the present disclosure.

Unless otherwise defined, all of the technical and scientific terms used herein have the same meanings as would generally understood by the person skilled in the technical field of the present disclosure. In this document, the terms used in the specification of the present disclosure is merely for the purpose of describing particular embodiments, and is not intended to limit the present disclosure.

It can be understood that the term “first”, “second”, etc. may be used in the present disclosure to describe various elements, but these elements are not limited by these terms. These terms are merely used for distinguishing a first element from another element. For example, a first resistor may be referred to as a second resistor without departing from the scope of the present disclosure; similarly, the second resistor may be referred to as the first resistor. The first resistor and the second resistor are both resistors, but not the same resistor.

It can be understood that “a connection” in the following embodiments should be interpreted as “an electrical connection”, “a communication connection” or the like if a connected circuit/module/unit/etc. has a transmission of an electrical signal or data between each other.

When used herein, a singular form of “a”, “one” or “the” may also mean plurals, unless otherwise clearly specified in the context. It should be further understood that the term “comprise/include”, “have” or the like specifies the presence of the described feature, integral, step, operation, component, portion, or the combination thereof, but not excluding the possibility of the presence or addition of one or more other feature, integral, step, operation, component, portion, or the combination thereof. Meanwhile, the term “and/or” used in the specification means that any or all combinations of the listed relevant items are included.

A machine is an assistance apparatus in a wafer manufacture process, which is configured to bear a manufactured wafer. During the manufacture process, since plasma generated from a sprayer have different intensities, and due to a position where a gas extractor is disposed, the gas extractor has an extraction efficiency inside a wafer surface different from outside the wafer surface, thereby affecting an efficiency of generating a wafer film, and causing the manufactured wafer to have a high or low point in an interval, which causes the wafer to have a defect of poor uniformity and flatness, and affects a product yield.

The present disclosure provides a machine including a body 10 and an adjustment part 20. The body 10 is configured to bear a wafer; the adjustment part 20 is disposed in the body 10 and uses a vacuum suction to adjust a levelness of an in-process wafer.

In the manufacture process of the wafer, a sprayer above the machine supplies a plasma gas flow, and a gas extractor located on a circumferential side of the machine provides a draft, which acts on the plasma gas flow to adjust its flow rate, so as to expedite a reaction rate of the plasma on the machine, and then speed up a rate of generating a wafer surface film. The adjustment part 20 is configured to generate a vacuum suction on a portion of the body 10 bearing the wafer, such that a lower surface of the wafer from center to periphery has different degrees of pressing close to a carrying surface 11, and then the levelness of the in-process wafer is optimized.

In embodiments of the present disclosure, the use of the adjustment by the adjustment part 20 may effectively reduce a phenomenon of a non-uniform distribution of the plasma on the machine due to a gas extractor exerting different gas extraction efficiencies on the plasma gas flow, thereby effectively solving the problem of the poor levelness of the wafer.

In some embodiments, since the gas extractor is arranged on the circumferential side of the machine in the wafer manufacture process, the gas extractor is relatively far away from a central region of the machine, and then the gas extractor has a low gas extraction efficiency on a central region of the plasma gas flow; and based on the low gas extraction efficiency of the gas extractor, the plasma in the central region of the machine may complete the reaction faster (i.e., the reaction rate of the plasma is relatively high in the central region of the machine), thereby causing a thickness of the manufactured wafer to be greater at its center which may also be interpreted as a high or low point in an interval occurring in the wafer, and affecting a product yield of the wafer.

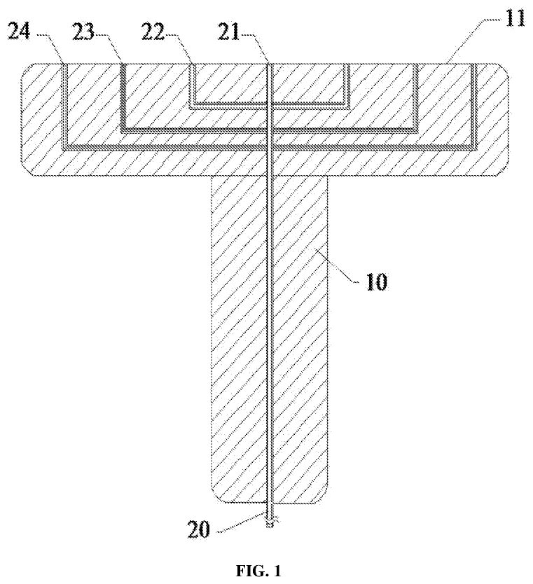

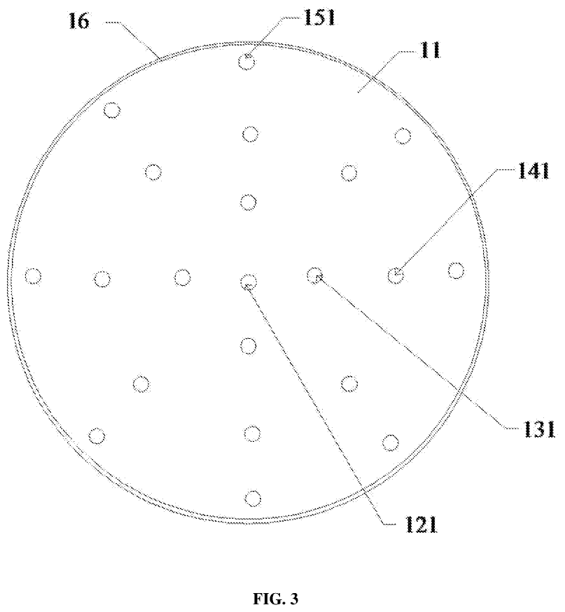

Based on the problem described above, in some embodiments, the body 10 includes a carrying surface 11, and the in-process wafer is placed on the carrying surface 11, as shown in FIGS. 1 to 4. The adjustment part 20 is arranged at the central portion of the carrying surface 11 to adjust the levelness of the central region of the in-process wafer.

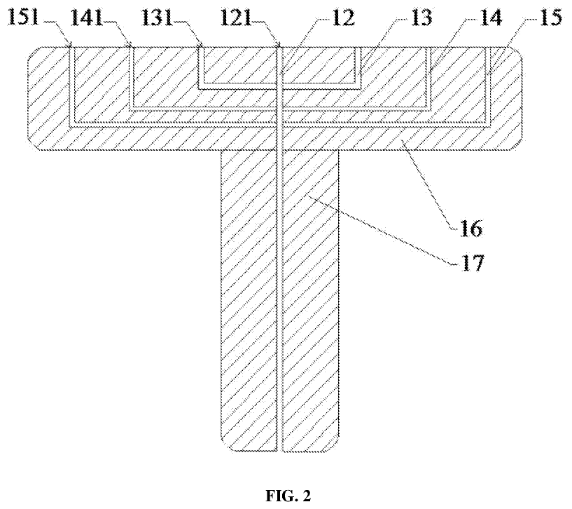

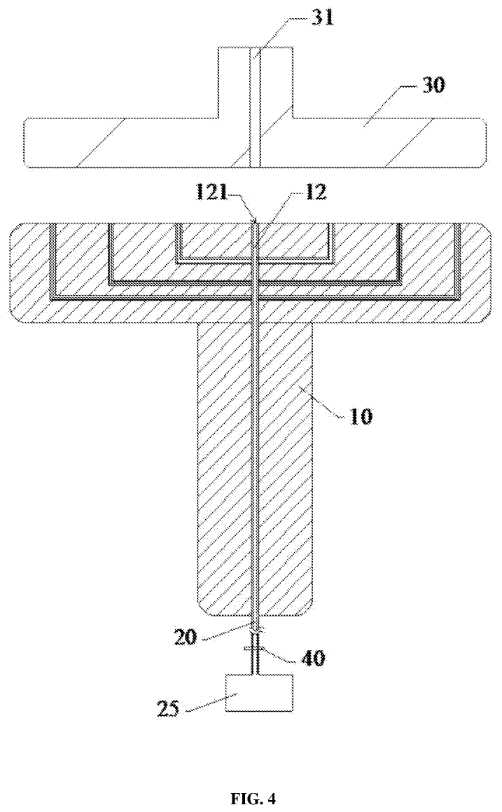

The body 10 is formed with a first gas guide channel 12 running through the carrying surface 11, and a gas intake port of the first gas guide channel 12 is formed at the central portion of the carrying surface 11. Referring to FIG. 2, a first gas intake port 121 of the first gas guide channel 12 is schematically shown. The adjustment part 20 includes a vacuum generator 25 (referring to FIG. 4) and a first vacuum line 21 disposed in the first gas guide channel 12. One end of the first vacuum line 21 is connected to the vacuum generator 25, and the other end of the first vacuum line 21 is connected with the gas intake port of the first gas guide channel 12. The vacuum generator 25 is a vacuum pump.

The first vacuum line 21 enables a negative pressure to be formed at the gas intake port (the first gas intake port 121) of the first gas guide channel 12 based on a vacuum suction generated by the vacuum generator 25, so as to adjust the levelness of the in-process wafer.

In the embodiments of the present disclosure, by arranging the adjustment part 20 at the central portion of the carrying surface 11 and using the vacuum suction generated by the adjustment part 20 to form the negative pressure at the first gas intake port 121, the vacuum suction of the carrying surface 11 of the machine to the wafer is reinforced and the lower surface of the wafer from center to periphery has different degrees of pressing close to the carrying surface 11, which is advantageous to guarantee the levelness of the central region of the processed wafer.

In order to guarantee the levelness of the entire wafer, in some embodiments, the adjustment part 20 further includes a second vacuum line 22, a third vacuum line 23, and a fourth vacuum line 24. A second gas guide channel 13, a third gas guide channel 14, and a fourth gas guide channel 15 are formed on the body 10. The second vacuum line 22 is disposed in the second gas guide channel 13, the third vacuum line 23 is disposed in the third gas guide channel 14, and the fourth vacuum line 24 is disposed in the fourth gas guide channel 15.

Corresponding ends of the second vacuum line 22, the third vacuum line 23, and the fourth vacuum line 24 are connected to the vacuum generator 25, and the other corresponding ends of the second vacuum line 22, the third vacuum line 23, and the fourth vacuum line 24 are connected with corresponding gas intake ports. Referring to FIG. 2, schematically illustrated are a second gas intake port 131 of the second gas guide channel 13, a third gas intake port 141 of the third gas guide channel 14, and a fourth gas intake port 151 of the fourth gas guide channel 15.

In the embodiments of the present disclosure, by arranging the second vacuum line 22, the third vacuum line 23, and the fourth vacuum line 24 on the body 10, pressures in different vacuum lines are controlled separately and the flexibility is high.

In some embodiments, in a direction from the central portion of the carrying surface 11 towards an edge of the carrying surface 11, the respective gas intake ports of the first gas guide channel 12, the second gas guide channel 13, the third gas guide channel 14, and the fourth gas guide channel 15 which are formed at the carrying surface 11 are arranged apart arranged apart, i.e., the first gas intake port 121, the second gas intake port 131, the third gas intake port 141, and the fourth gas intake port 151 are arranged apart. The gas intake ports corresponding to the first gas guide channel 12, the second gas guide channel 13, the third gas guide channel 14, and the fourth gas guide channel 15 are arranged at equal or unequal intervals. In an embodiment, the gas intake ports corresponding to the first gas guide channel 12, the second gas guide channel 13, the third gas guide channel 14, and the fourth gas guide channel 15 are arranged at equal intervals.

In the embodiments of the present disclosure, the equidistant arrangement of the gas intake ports corresponding to the first gas guide channel 12, the second gas guide channel 13, the third gas guide channel 14, and the fourth gas guide channel 15 may achieve on the machine an feature that the lower surface of the wafer from center to periphery has different degrees of pressing close to the carrying surface 11, thereby achieving a more precise control over the levelness of the processed wafer and guaranteeing the product yield of the wafer.

In some other embodiments, a plurality of the second gas guide channels 13 and a plurality of the second vacuum lines 22 are provided and disposed in an one-to-one correspondence, and the gas intake ports corresponding to the plurality of the second gas guide channels 13 form an annular shape and are arranged around the gas intake port of the first gas guide channel 12.

In the embodiments of the present disclosure, the gas intake ports corresponding to the plurality of the second gas guide channels 13 form an annular region, the adjustment to the negative pressure which is applied to the wafer at the annular region on the carrying surface 11 is enabled based on the vacuum suction of the plurality of the second vacuum lines 22, and in each annular region, the wafer has a different degree of pressing close to the carrying surface 11 by virtue of a characteristic of negative pressure adjustment differences between different annular regions, thereby guaranteeing the levelness of the processed wafer.

Similarly, in some embodiments, a plurality of the third gas guide channels 14 and a plurality of the third vacuum lines 23 are provided and disposed in an one-to-one correspondence, and the gas intake ports corresponding to the plurality of the third gas guide channels 14 form an annular shape and are arranged around the gas intake port of the first gas guide channel 12.

In the above embodiments of the present disclosure, the gas intake ports corresponding to the plurality of the third gas guide channels 14 form an annular region, the adjustment to the negative pressure which is applied to the wafer at the annular region on the carrying surface 11 is enabled based on the vacuum suction of the plurality of the third vacuum line 23, and in each annular region, the wafer has a different degree of pressing close to the carrying surface 11 by virtue of a characteristic of negative pressure adjustment differences between different annular regions, thereby guaranteeing the levelness of the processed wafer.

In yet some embodiments, a plurality of the fourth gas guide channels 15 and a plurality of the fourth vacuum lines 24 are provided and disposed in a one-to-one correspondence, and the gas intake ports corresponding to the plurality of the fourth gas guide channels 15 form an annular shape and are arranged around the gas intake port of the first gas guide channel 12.

In the embodiments of the present disclosure, the gas intake ports corresponding to the plurality of the fourth gas guide channels 15 form an annular region, the adjustment to the negative pressure which is applied to the wafer at the annular region on the carrying surface 11 is enabled based on the vacuum suction of the plurality of the fourth vacuum line 24, and in each annular region, the wafer has a different degree of pressing close to the carrying surface 11 by virtue of a characteristic of negative pressure adjustment differences between different annular regions, thereby guaranteeing the levelness of the processed wafer.

In order to enable dynamic adjustments, the machine further includes a plurality of pressure control members 40. The plurality of pressure control members 40 are respectively disposed on the first vacuum line 21, the second vacuum line 22, the third vacuum line 23, and the fourth vacuum line 24. The pressure control member 40 is configured to adjust flows in the first vacuum line 21, the second vacuum line 22, the third vacuum line 23 and the fourth vacuum line 24, so as to control a magnitude of the negative pressure at the gas intake port corresponding to the first gas guide channel 12, the second gas guide channel 13, the third gas guide channel 14 or the fourth gas guide channel 15. The pressure control member 40 includes, but not limited to, a pressure regulating valve.

In the embodiments of the present disclosure, by using the pressure control member 40, the dynamic adjustment may be enabled for the vacuum suction in the first vacuum line 21, the second vacuum line 22, the third vacuum line 23, and the fourth vacuum line 24, such that the adjustment part 20 has an ability of adaptive adjustment based on a process requirement of the manufacture, and thus, a practicability of the machine according to the present disclosure may be significantly improved.

In some embodiments, the vacuum suction in the first vacuum line 21, the second vacuum line 22, the third vacuum line 23, and the fourth vacuum line 24 are decreased successively by the pressure control member 40.

In the embodiments of the present disclosure, the gas intake ports corresponding to the plurality of the second gas guide channels 13 form an annular region, the gas intake ports corresponding to the plurality of the third gas guide channels 14 form an annular region, and the gas intake ports corresponding to the plurality of the fourth gas guide channels 15 form an annular region; the vacuum suction in the first vacuum line 21, the second vacuum line 22, the third vacuum line 23, and the fourth vacuum line 24 are decreased successively, such that the vacuum suction for the wafer is adjusted on the machine by the adjustment part 20, and the lower surface of the wafer from center to periphery has different degrees of pressing close to the carrying surface, thereby guaranteeing the levelness of the processed wafer.

The body 10 includes a bearing plate 16 and a supporting seat 17 connected to the bearing plate 16. The carrying surface 11 is formed on the bearing plate 16. All of the first gas guide channel 12, the second gas guide channel 13, the third gas guide channel 14, and the fourth gas guide channel 15 run through the supporting seat 17 and the bearing plate 16. The first gas guide channel 12, the second gas guide channel 13, the third gas guide channel 14, and the fourth gas guide channel 15 are connected at their portions disposed in the supporting seat 17.

In some embodiments, the pressures in the first vacuum line 21, the second vacuum line 22, the third vacuum line 23, and the fourth vacuum line 24 are adjusted to be 0.1 torr to 10 torr.

According to a second aspect of the present disclosure, a wafer processing apparatus is provided. The wafer processing apparatus includes a housing, at least one machine, a gas extractor, and a gas feeder 30. The housing is provided with a reaction chamber; the machine is disposed in the reaction chamber; the gas extractor is disposed in the reaction chamber and configured to adjust an efficiency of producing a wafer on the machine in a manufacture process; the gas feeder 30 is disposed in the reaction chamber and arranged opposite to the machine.

In some embodiments, the gas feeder 30 is formed with a gas feed channel 31. The gas intake port of the first gas guide channel 12 in the machine is formed to correspond to a position of a gas vent port of the gas feed channel 31.

In the embodiments of the present disclosure, the gas intake port of the first gas guide channel 12 is formed to correspond to the position of the gas vent port of the gas feed channel 31, and by using the vacuum suction which is generated by the adjustment part 20 to strengthen the vacuum suction to the wafer at the central portion of the machine, the carrying surface 11 at the central portion of the machine is pressed closer to the wafer than the carrying surface 11 in the peripheral region of the machine, which is advantageous to guarantee the levelness of the central region of the processed wafer.

In some embodiments, the first gas guide channel 12 is coaxially arranged with the gas feed channel 31.

The first gas guide channel 12 is formed to be coaxially arranged with the gas feed channel 31, such that the wafer on the carrying surface has a same plasma density at equal positions in radial directions, guaranteeing the levelness of the central region of the processed wafer.

In description of the specification, the reference terms such as “some embodiments”, “other embodiments”, and “ideal embodiments” mean that the specific feature, structure or material, which is described in combination with these embodiments or examples, are included in at least one embodiment or example of the present disclosure. In the specification, the schematic description of the above terms does not necessarily refer to the same embodiments or examples.

Technical features of the embodiments described above may be arbitrarily combined, but not all of the potential combinations are described so as to make the description concise. However, all of the combinations of these technical features should be considered as the scope recited in the specification as long as they have no conflict therein.

The embodiments described above merely show several implementations of the present disclosure. The descriptions thereof are specific and detailed, but should not be interpreted as limiting the scope of the patent disclosure. It should be noted that the person skilled in the art could further make several variations and improvements without departing the concept of the present disclosure, and these variations and improvements belong to the scope sought for protection in the present disclosure. Therefore, the protection scope of the present patent disclosure shall be subject to the claims.

What is claimed is:

1. A machine, comprising:
a body configured to bear a wafer; and
an adjustment part disposed in the body, the adjustment part using a vacuum suction to adjust a levelness of an in-process wafer.

2. The machine according to claim 1, wherein
the body comprises a carrying surface, the in-process wafer being placed on the carrying surface; and
the adjustment part is arranged at a central portion of the carrying surface to adjust a levelness of a central region of the in-process wafer.

3. The machine according to claim 2, wherein
the body is formed with a first gas guide channel running through the carrying surface, and a gas intake port of the first gas guide channel is formed at the central portion of the carrying surface;
the adjustment part comprises a vacuum generator and a first vacuum line disposed in the first gas guide channel, an end of the first vacuum line is connected to the vacuum generator, and the other end of the first vacuum line is connected with the gas intake port of the first gas guide channel;
wherein the first vacuum line enables a negative pressure to be formed at the gas intake port of the first gas guide channel based on a vacuum suction generated by the vacuum generator, so as to adjust the levelness of the in-process wafer.

4. The machine according to claim 3, wherein
the adjustment part further comprises: a second vacuum line, a third vacuum line, and a fourth vacuum line; the body has a second gas guide channel, a third gas guide channel, and a fourth gas guide channel formed thereon; the second vacuum line is disposed in the second gas guide channel, the third vacuum line is disposed in the third gas guide channel, and the fourth vacuum line is disposed in the fourth gas guide channel;
wherein corresponding ends of the second vacuum line, the third vacuum line, and the fourth vacuum line are connected to the vacuum generator, and the other corresponding ends of the second vacuum line, the third vacuum line, and the fourth vacuum line are connected with corresponding gas intake ports.

5. The machine according to claim 4, wherein
in a direction from the central portion of the carrying surface towards an edge of the carrying surface, the respective gas intake ports of the first gas guide channel, the second gas guide channel, the third gas guide channel, and the fourth gas guide channel which are formed at the carrying surface are arranged apart.

6. The machine according to claim 5, wherein
a plurality of the second gas guide channels and a plurality of the second vacuum lines are provided and disposed in a one-to-one correspondence, and the gas intake ports corresponding to the plurality of the second gas guide channels form an annular shape and are arranged around the gas intake port of the first gas guide channel.

7. The machine according to claim 5, wherein
a plurality of the third gas guide channels and a plurality of the third vacuum lines are provided and disposed in a one-to-one correspondence, and the gas intake ports corresponding to the plurality of the third gas guide channels form an annular shape and are arranged around the gas intake port of the first gas guide channel.

8. The machine according to claim 5, wherein
a plurality of the fourth gas guide channels and a plurality of the fourth vacuum lines are provided and disposed in a one-to-one correspondence, and the gas intake ports corresponding to the plurality of the fourth gas guide channels form an annular shape and are arranged around the gas intake port of the first gas guide channel.

9. The machine according to claim 5, further comprising:
a plurality of pressure control members respectively disposed on the first vacuum line, the second vacuum line, the third vacuum line, and the fourth vacuum line, the pressure control member is configured to adjust flows in the first vacuum line, the second vacuum line, the third vacuum line and the fourth vacuum line, so as to control a magnitude of the negative pressure at the gas intake port corresponding to the first gas guide channel, the second gas guide channel, the third gas guide channel or the fourth gas guide channel.

10. The machine according to claim 9, wherein
vacuum suction in the first vacuum line, the second vacuum line, the third vacuum line, and the fourth vacuum line are decreased successively by the pressure control member.

11. The machine according to claim 5, wherein
the body comprises a bearing plate and a supporting seat connected to the bearing plate, the carrying surface being formed on the bearing plate;
all of the first gas guide channel, the second gas guide channel, the third gas guide channel, and the fourth gas guide channel run through the supporting seat and the bearing plate;
wherein the first gas guide channel, the second gas guide channel, the third gas guide channel, and the fourth gas guide channel are connected at their portions disposed in the supporting seat.

12. The machine according to claim 5, wherein
pressures in the first vacuum line, the second vacuum line, the third vacuum line, and the fourth vacuum line are adjusted to be 0.1 torr to 10 torr.

13. A wafer processing apparatus, comprising:
a housing with a reaction chamber;
at least one machine according to claim 1, the machine being disposed in the reaction chamber;
a gas extractor disposed in the reaction chamber, the gas extractor being configured to adjust an efficiency of producing a wafer on the machine during a manufacture process; and
a gas feeder disposed in the reaction chamber, the gas feeder being arranged opposite to the machine.

14. The apparatus according to claim 13, wherein
the gas feeder is formed with a gas feed channel; wherein a gas intake port of a first gas guide channel in the machine is formed to correspond to a position of a gas vent port of the gas feed channel.

15. The apparatus according to claim 14, wherein
the first gas guide channel is coaxially arranged with the gas feed channel.
